(19) United States
(12) Patent Application Publication
(10) Pub. No.: US 2011/0233533 A1
(43) Pub. Date: Sep. 29, 2011

(54) ORGANIC THIN FILM DEVICE

(75) Inventors: Jin Jang, Seoul (KR); Mi-Sun Ryu, Seoul (KR)

(73) Assignee: KYUNGHEE UNIVERSITY INDUSTRIAL & ACADEMIC COLLABOR -ATION FOUNDATION, Seoul (KR)

(21) Appl. No.: 13/120,403

(22) PCT Filed: May 19, 2009
(86) PCT No.: PCT/KR2009/002626

§ 371 Date: Jun. 7, 2011

(30) Foreign Application Priority Data
Sep. 23, 2008 (KR) 10-2008-0093006

(51) Int. Cl. H01L 51/30

(52) U.S. Cl. 257/40; 257/E51.039

(57) ABSTRACT

Disclosed herein is an organic thin film device. The organic thin film device includes a UV barrier layer, which has a UV blocking effect, in addition to at least one electrode and at least one organic semiconductor layer on a substrate. The organic thin film device employs a film or a coating liquid which comprises phenolic derivatives or cyanoacrylate derivatives exhibiting a UV-blocking effect in a wavelength of 400 nm or less, so that photodecomposition of an organic material for use in fabrication of the organic thin film device by UV rays and sunlight can be minimized, thereby innovatively increasing lifetime of the device.

### TECHNICAL FIELD

The present invention relates to organic thin film devices and, more particularly, to an organic thin film device that employs a film or a coating liquid exhibiting a UV-blocking effect at a wavelength of 400 nm or less to minimize photodecomposition of an organic material for use in fabrication of the organic thin film device by UV and sunlight, thereby innovatively increasing lifetime of the device.

### BACKGROUND ART

In recent years, demand for clean alternative energy has dramatically increased due to high fuel price and environmental contamination, and development of alternative energy sources, such as hydrogen/fuel cells, solar cells, wind energy, and the like, has been intensively encouraged throughout the world. Particularly, solar cell industries have been rapidly expanded in order to meet high demand for crystalline silicon-based solar cells mainly manufactured in the market and lack of supply of silicon raw materials therefor. In this regard, increase in lifetime of conventional solar cells can be an innovative solution to current problems in a different point of view from fulfillment of the excessive demand.

Generally, an organic thin film solar cell has a metal/organic semiconductor (photoactive layer)/metal structure as shown in FIG. 1. Further, the organic thin film solar cell employs an ITO transparent electrode having a high work function as a cathode, and Al or Ca, as an anode material, which has a low work function. The photoactive layer generally has a double-layer structure (see (a) in FIG. 1) of an electron donor D and an electron acceptor A each having a thickness of about 100 nm or a composite thin film structure (see (b) in FIG. 1). In some cases, the photoactive layer can employ a combined structure wherein the composite thin film is interposed between the electron donor and acceptor layers.

On the other hand, the organic semiconductor used as the photoactive layer can be formed using organic monomers and organic polymers. For the organic monomers, the organic semiconductor layer is formed using a method of continuously forming a donor layer and an acceptor layer by heating the organic monomers in a vacuum. For the organic polymers, the organic semiconductor layer is formed by a wet process such as spin coating, ink jet printing or screen printing using a liquid, which has donor and acceptor materials dissolved therein.

Operation of the organic thin film solar cell will be briefly described hereinafter.

When light is irradiated to the organic thin film solar cell, the donor material absorbs the light to form electron-hole pairs in an excited state, which in turn are separated into electrons and holes. Here, the electrons move toward the acceptor having high electron affinity and the holes remain in the donor, so that the electron-hole pairs are separated to the respective charge states. Then, the electrons and holes move to the associated electrodes to be accumulated therein by a difference between concentration of accumulated charges and an internal electric field, which is created due to a difference in work function between both electrodes, and finally flow as an electric current through an external circuit.

However, when sunlight is irradiated to such an organic thin film device, the organic material of the device is decomposed by UV rays, thereby reducing lifetime of the device. Hence, if photodecomposition of the organic material for use in fabrication of the organic thin film device can be minimized, it is possible to innovatively increase lifetime of the device, which will solve the aforementioned problem of excessive demand for the crystalline silicon-based solar cells while reducing manufacturing costs. Therefore, there is a need for a method of improving lifetime of the organic thin film device.

### DISCLOSURE OF INVENTION

### Technical Problem

The present invention is directed to solve the problem of the related art as described above, and an aspect of the present invention is to provide an organic thin film device that employs a film or a coating liquid exhibiting a UV-blocking effect at a wavelength of 400 nm or less to minimize photodecomposition of an organic material for use in fabrication of the organic thin film device by UV and sunlight, thereby innovatively increasing lifetime of the device.

### Technical Solution

In accordance with an aspect of the present invention, an organic thin film device including at least one electrode and at least one organic semiconductor layer on a substrate further includes a UV barrier layer which has a UV blocking effect.

The UV barrier layer may be formed by coating a film or a coating liquid which exhibits a UV-blocking effect in a wavelength of 400 nm or less. The film or the coating liquid forming the UV barrier layer may comprise phenolic derivatives or cyanoacrylate derivatives.

The UV barrier layer may be disposed on a rear side of the substrate.

The organic semiconductor layer may include an active organic thin film comprising polythiophene derivatives as an electron donor and fullerene derivatives as an electron acceptor.

The organic semiconductor layer may further include a titanium oxide layer between the active organic thin film and the electrode.

### Advantageous Effects

According to one embodiment of the invention, the organic thin film device is formed using a film and a coating liquid exhibiting a UV-blocking effect at a wavelength of 400 nm or less to minimize photodecomposition of an organic material for use in fabrication of the organic thin film device by UV and sunlight, thereby innovatively increasing lifetime of the device.

### BRIEF DESCRIPTION OF DRAWINGS

The above and other aspects, features and advantages of the present invention will be more clearly understood from the following detailed description taken in conjunction with the accompanying drawings, in which:

FIG. 1 is a schematic view of a conventional organic thin film device;

FIG. 2 is a diagram of an organic thin film device including a UV barrier film according to one embodiment of the present invention;

FIG. 3 is a graph depicting UV spectrum of a UV barrier film for use in fabrication of an organic thin film device according to one embodiment of the present invention and spectrum of AM 1.5 sunlight used for light irradiation;

FIGS. 4 and 5 are J-V characteristic curves obtained in a condition of AM 1.5, and after using the UV barrier film according to the embodiment of the present invention, respectively;

FIGS. 6, 7, 8, and 9 are graphs depicting open circuit current, short circuit voltage, fill factor, and energy conversion efficiency according to light irradiation time to solar cell devices including the UV barrier film and not including the UV barrier film, respectively; and

FIG. 10 is a graph depicting variance of parameters according to light irradiation time to the solar cell devices including the UV barrier film and not including the UV barrier film.

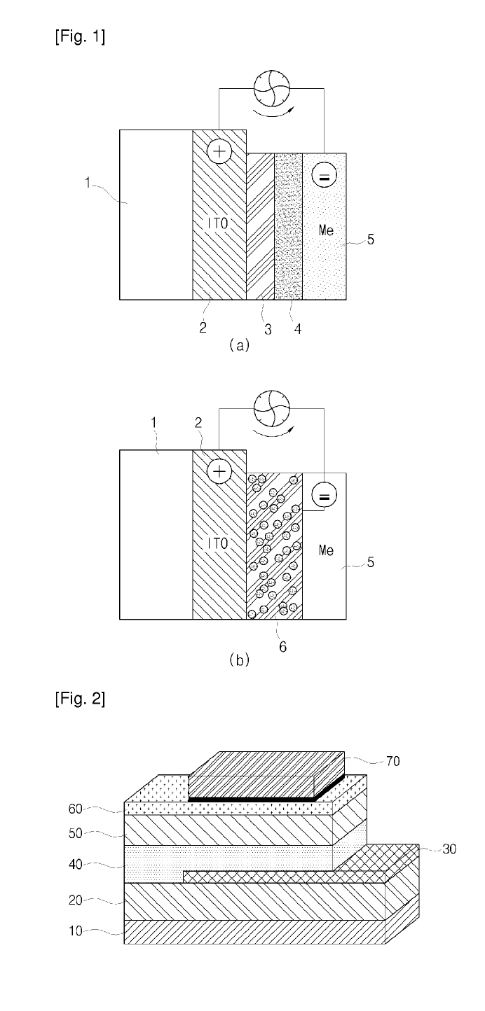

### BEST MODE FOR CARRYING OUT THE INVENTION

According to one embodiment of the present invention, an organic thin film device including at least one electrode and at least one organic semiconductor layer on a substrate further includes a UV barrier layer which has a UV blocking effect.

### Mode for the Invention

Embodiments of the present invention will now be described in more detail with reference to the accompanying drawings.

FIG. 2 shows an organic thin film device, that is, an organic solar cell device, including a UV barrier film according to one embodiment of this invention.

The organic thin film device according to this embodiment includes a glass or plastic substrate 20, an ITO electrode 30, organic material layers, specifically, a hole delivering layer 40 and an organic active layer 50, and an Al electrode 70, which are deposited in this order. The organic thin film device may further include a titanium oxide layer 60 between the organic active layer and the Al electrode. According to this embodiment, the organic thin film device includes a UV barrier layer 10 formed to prevent decomposition of the organic material layer by UV rays in a sunlight absorbing structure.

The UV barrier layer 10 may be formed by forming a thin film using a film or a coating liquid, which may comprise phenolic derivatives or cyanoacrylate derivatives. The film and coating liquid may exhibit a UV-blocking effect in a wavelength of 400 nm or less.

An organic semiconductor layer composed of the organic material layer may include the organic active layer (active organic thin film) 50. Here, the active organic thin film may comprise polythiophene derivatives as an electron donor and fullerene derivatives as an electron acceptor.

In other words, the organic thin film device according to the embodiment of this invention includes the thin film capable of effectively blocking UV rays on the rear side of the device to minimize variance of main parameters, such as short-circuit current, open voltage, fill factor, and the like, for improving energy conversion efficiency of a solar cell, thereby realizing a device which can minimize variance in energy conversion efficiency.

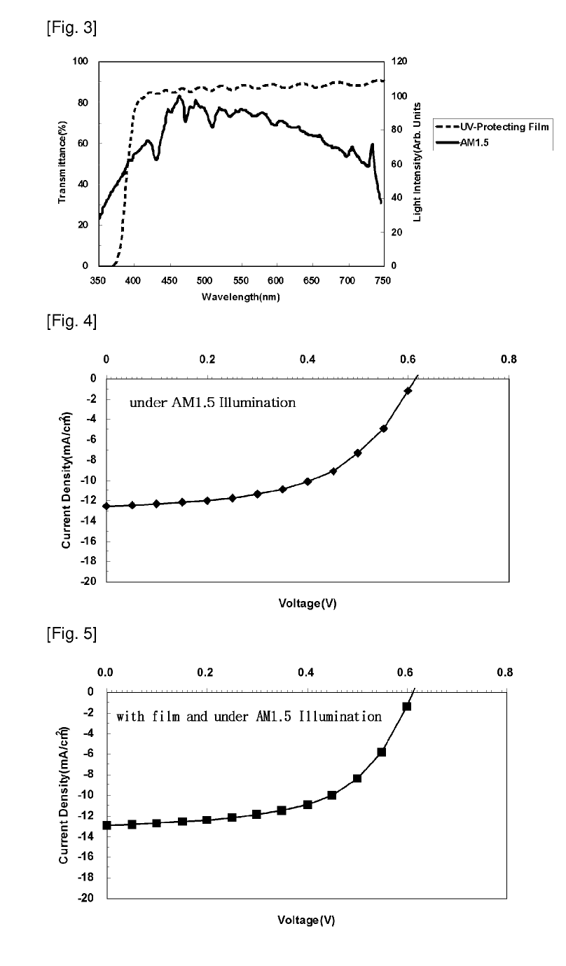

FIG. 3 is a graph depicting UV spectrum of a UV barrier film for use in fabrication of an organic thin film device according to one embodiment of the present invention and spectrum of AM 1.5 sunlight used for light irradiation.

Since the UV barrier film according to the embodiment of this invention has high transmittance in the wavelength range of visible light, the UV barrier film does not provide any influence on sunlight absorption by the device and thus does not provide any influence on reduction of energy conversion efficiency of the device.

Particularly, FIGS. 4 and 5 show current density-voltage characteristics curves of organic thin film devices fabricated using the UV barrier film according to the embodiment of this invention and without the UV barrier film, respectively. It can be seen from FIGS. 4 and 5 that both devices have a similar short circuit current density of about 13 mA/cm².

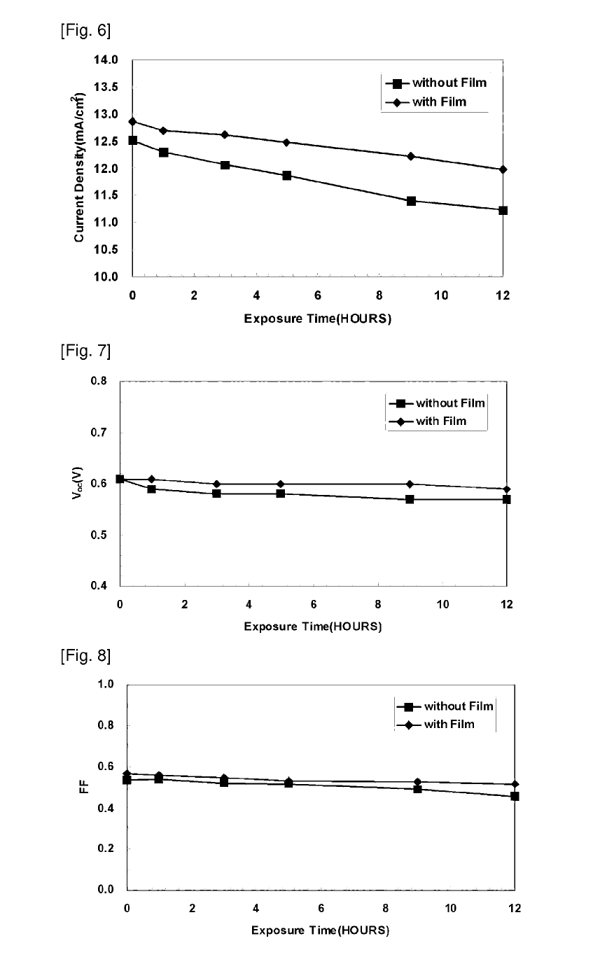

FIGS. 6 to 10 show variance of parameters according to sunlight irradiation time for solar cell devices including the UV barrier film and not including the UV barrier film.

FIG. 6 is a graph depicting current density-voltage characteristics of the solar cell devices when sunlight was irradiated for 12 hours without interruption. It can be seen from FIG. 6 that the solar cell device including the UV barrier film exhibited a current density variation from 12.9 mA/cm² to 12.0 mA/cm², whereas the solar cell device not including the UV barrier film exhibited a current density variation from 12.5 mA/cm² to 11.2 mA/cm².

FIG. 7 is a graph depicting open voltage characteristics of the solar cell devices according to sunlight irradiation time. It can be seen from FIG. 7 that the solar cell device including the UV barrier film showed a small variation of open voltage from 0.61V to 0.59V. Further, it can be seen from fill factor characteristics of FIG. 8 that the solar cell device including the UV barrier film showed a small variation.

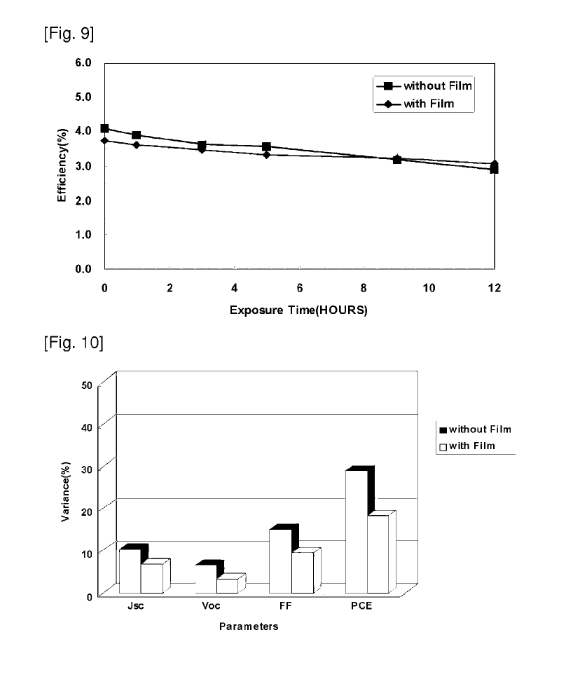

As a result, it can be seen from FIG. 9 showing energy conversion efficiency according to sunlight irradiation time that the solar cell device including the UV barrier film showed a small variation.

FIG. 10 is a graph depicting variance of parameters according to sunlight irradiation time for the solar cell devices including the UV barrier film and not including the UV barrier film. It can be seen from FIG. 10 that the solar cell device including the UV barrier film showed smaller variations of all parameters. As a result, it can be verified that, when using the UV barrier film, lifetime of the organic solar cell device can be effectively improved by minimizing variance of the respective parameters. That is, according to the present invention, the organic thin film device employs the film or the coating liquid which comprises phenolic derivatives or cyanoacrylate derivatives exhibiting the UV-blocking effect in a wavelength of 400 nm or less, so that photodecomposition of the organic material for use in fabrication of the organic thin film device by UV rays and sunlight can be minimized, thereby innovatively increasing lifetime of the device.

Although some exemplary embodiments have been provided to illustrate the present invention, it should be noted that the present invention is not limited to the embodiments and that various modifications, additions and substitutions can be made by a person having ordinary knowledge in the art without departing from the scope of the invention. Therefore, the spirit and scope of the present invention should be limited only by the accompanying claims and equivalents thereof.

### INDUSTRIAL APPLICABILITY

According to the present invention, the organic thin film device employs a film and a coating liquid exhibiting a UV-blocking effect at a wavelength of 400 nm or less to minimize photodecomposition of an organic substance for use in fabrication of the organic thin film device by UV and sunlight, thereby innovatively increasing lifetime of the device.

1. In an organic thin film device including at least one electrode and at least one organic semiconductor layer on a substrate, the improvement comprising: a UV barrier layer which has a UV blocking effect.

2. The organic thin film device according to claim 1, wherein the UV barrier layer is formed by coating a film or a coating liquid which exhibits a UV-blocking effect in a wavelength of 400 nm or less.

3. The organic thin film device according to claim 2, wherein the film or the coating liquid forming the UV barrier layer comprises phenolic derivatives or cyanoacrylate derivatives.

4. The organic thin film device according to claim 3, wherein the UV barrier layer is disposed on a rear side of the substrate.

5. The organic thin film device according to any one of claims 1 to 4, wherein the organic semiconductor layer comprises an active organic thin film, the active organic thin film comprising polythiophene derivatives as an electron donor and fullerene derivatives as an electron acceptor.

6. The organic thin film device according to claim 5, further comprising:
a titanium oxide layer between the active organic thin film and the electrode.
